(19) United States
(12) Patent Application Publication
(10) Pub. No.: US 2003/0232466 A1
(43) Pub. Date: Dec. 18, 2003

(54) Diffusion barrier layer in semiconductor substrates to reduce copper contamination from the back side

(76) Inventors: Christian Zistl, Dresden (DE); Johannes Groschopf, Wainsdorf (DE); Massud Aminpur, Dresden (DE)

Correspondence Address: J. Mike Amerson, Williams, Morgan & Amerson, P.C., Suite 1100, 10333 Richmond, Houston, TX, 77042, US

(21) Appl. No.: 10/306,497

(22) Filed: Nov. 27, 2002

(30) Foreign Application Priority Data
May 31, 2002 (DE) 102 24 160.0

(51) Int. Cl. H01L 21/00; H01L 21/44

(52) U.S. Cl. 438/164; 438/149; 438/458; 438/459

(57) ABSTRACT

An SOI substrate includes a diffusion barrier layer, the layer thickness and composition of which is selected so as to substantially prevent copper atoms and ions from diffusing through the diffusion barrier layer. The diffusion barrier layer is located to substantially reduce the deleterious effect of copper that may be introduced into a semiconductor device from the back side of the substrate during various manufacturing stages of the semiconductor device. In one particular example, a silicon wafer with a silicon nitride layer as a diffusion barrier layer and a silicon wafer with an oxide layer is bonded. After separation, an SOI substrate is obtained that has superior characteristics with respect to resistance against copper back side diffusion.

### BACKGROUND OF THE INVENTION

1. Field of the Invention

Generally, the present invention relates to the field of fabrication of integrated circuits, and, more particularly, to the formation of semiconductor devices including copper layers and structures.

2. Description of the Related Art

An integrated circuit typically contains a huge number of individual circuit elements, such as transistors, resistors, capacitors and the like, the dimensions of which are steadily decreasing. Recently, critical dimensions of circuit elements have reached 0.18 μm, with the prospect of 0.13 μm in the near future. Although the reduction of feature sizes brings about a plurality of advantages, in terms of performance of the individual circuit elements and the number of circuit elements that may be provided within a specified chip area, other major issues may arise that may possibly offset the advantages obtained by steadily reducing feature sizes. One dominant problem in this respect is the fact that reducing the feature sizes may also adversely impact the metal lines provided to electrically connect the circuit elements according to the functionality of the circuit.

As the amount of individual circuit elements per unit area increases, the number of interconnect lines for these elements also increases, typically faster than the number of circuit elements, and requires a drastic reduction in size of the metal lines, which conventionally have been formed by aluminum. Since aluminum suffers from intolerable high electromigration at elevated levels of current density, the dimensions of aluminum lines may not arbitrarily be reduced. Consequently, in sophisticated integrated circuits having minimum feature sizes of, for example, 0.13 μm or less, the signal propagation delay is no longer determined by the individual circuit elements, such as transistors and the like, but is mainly caused by the large RC time constants generated by the metal lines and the adjacent dielectric material.

Consequently, semiconductor manufacturers are increasingly using copper as a metallization material due to its superior properties compared to aluminum. For example, copper has low resistivity, high reliability, high heat conductivity, and a relatively fine crystalline structure that is controllable. On the other hand, the introduction of copper into the fabrication process of integrated circuits involves a plurality of issues, of which one of the most challenging tasks is the elimination or minimization of copper contamination, since copper readily diffuses in silicon devices. Diffusion of copper in the semiconductor devices may lead primarily to two types of failures: the degradation of insulating layers in the interconnect layer resulting in a short or leakage path between the copper lines, and high leakage currents in the individual transistor elements due to the copper's property of forming a deep-level trap in the silicon band gap. Copper is known to rapidly diffuse in silicon under moderate temperatures with a diffusion coefficient that is significantly higher than that of gold, silver, sodium and iron. Moreover, under moderate temperatures, and with a relatively low bias voltage, ionic copper also diffuses in many dielectric materials. For this reason, prior to depositing copper on and into trenches and vias, a diffusion barrier layer has to be reliably formed within the vias and trenches to avoid any out-diffusion of copper into adjacent material layers. Typically, tantalum nitride, tantalum, titanium nitride and insulating silicon nitride may effectively be employed to encapsulate every single copper metal line and via to avoid diffusion of copper into the neighboring materials.

However, copper contamination may also arise from contacting the back side of the semiconductor substrate during the various manufacturing stages. For example, the manufacturing tools required for copper deposition and processing, such as a sputter deposition tool required for deposition of a copper seed layer, an electroplating reactor required for the bulk deposition of copper, a chemical mechanical polishing (CMP) tool and any associated cleaning tools, may produce a minute amount of copper at the bevel or on the back side of the substrate, which may then readily diffuse into sensitive areas during the following fabrication steps. In addition to the direct contamination by copper processing tools, the substrates may also receive tiny amounts of copper at the bevel or on the back side of the substrate by tools that are not directly involved in processing copper but have been contaminated by wafer handling, etc., since most of the substrate handling takes place on the bevel and back side of the substrates. Although semiconductor manufacturers take great care in avoiding copper contamination of process tools and substrates, there is nevertheless a great risk of copper diffusion into active areas by minute and hardly detectable amounts of copper on the bevel and the back side.

In addition to the provision of copper metallization layers, which as previously explained significantly enhances the signal propagation in the metal interconnects, semiconductor manufacturers are looking for new solutions in improving the performance of the individual circuit elements. A promising development in this respect has become the so-called SOI (silicon-on-insulator) technique, in which the transistor elements are formed within relatively thin semiconductor layers provided on an insulating layer on an appropriate substrate rather than forming the well regions in a bulk semiconductor material. Thus, contrary to conventional bulk semiconductors, SOI devices may be completely insulated from each other so that any latch up effects may be reduced or completely eliminated. Moreover, due to the complete insulation, leakage currents may be minimized and switching speed may be enhanced due to reduced parasitic capacitances in the active regions of the transistor elements. One major advantage of SOI devices compared to conventional bulk devices is the enhanced resistance of the SOI devices against radiation-induced errors, since SOI devices have a significantly smaller active silicon area as compared to bulk devices. Thus, the probability of a reaction of a high energetic particle, such as a cosmic ray particle, with a silicon core is significantly reduced.

Although the SOI technique seems very promising due to the above-mentioned advantages, in the past, semiconductor manufacturers have been reluctant to employ this technique for a variety of reasons. The reasons may include the higher costs involved in providing SOI substrates and the minor crystalline quality of the active silicon layer formed on the insulating layer which is usually a silicon dioxide and which is also often referred to as buried oxide (BOX). Recently, however, a plurality of methods have been developed allowing the provision of a thin silicon layer on a silicon dioxide layer that exhibits about the same crystalline quality as the active region in a conventional bulk device, wherein an undue material waste may be avoided so that prices of SOI substrates are comparable to those of substrates for bulk devices.

Accordingly, future high end circuit generations may be based on copper technology implemented into SOI devices including transistor elements having a reduced active area. Any minute copper contamination in such small-sized active areas may, however, exacerbate the problem of copper-induced device failure even more. Moreover, copper contamination of dielectrics may remarkably compromise the SOI device's superior characteristics with respect to leakage current and latch up. Thus, the present invention is directed at eliminating or at least reducing the problems involved in producing sophisticated integrated circuits using copper technology in SOI devices.

### SUMMARY OF THE INVENTION

In view of the above-mentioned problems, the present invention provides for a significantly reduced probability of device failures owing to copper contamination in semiconductor devices formed on an insulating substrate, such as SOI devices, in that a diffusion barrier is provided between a buried insulating layer, such as a silicon dioxide layer, and the bulk material of the substrate bearing the semiconductor devices. The copper diffusion barrier layer, which may also be considered as a copper gettering layer, effectively restricts the diffusion of copper from the back side into the insulating layer and thus into the minute active region of the circuit elements and thus contributes to production yield and reliability of the devices.

According to one illustrative embodiment of the present invention, an SOI substrate comprises a bulk material layer providing for the required mechanical stability of the substrate. Moreover, a diffusion barrier layer is provided on the bulk material layer that has a thickness and a composition that substantially prevents diffusion of copper from the bulk material layer into an overlying layer. Moreover, a silicon dioxide layer is formed over the diffusion barrier layer and a silicon layer is formed on the silicon dioxide layer.

According to a further embodiment of the present invention, a semiconductor device comprises a substrate, a buried insulating layer and a doped semiconductor layer formed on the buried insulating layer. The semiconductor device further comprises a copper-containing metal layer and a diffusion barrier layer arranged between the substrate and the buried insulating layer, wherein a composition and a thickness of the diffusion barrier layer is selected to substantially prevent copper from diffusing from the substrate into the buried insulating layer.

In a further illustrative embodiment of the present invention, a method for forming an SOI substrate, including a back side diffusion barrier, comprises forming a diffusion barrier layer on a first substrate, wherein the diffusion barrier layer has a composition and a thickness that substantially prevents copper from diffusing through the diffusion barrier layer at elevated temperatures prevailing during copper processing. Moreover, an oxide layer is formed on a second semiconductor containing substrate and the first and the second substrates are bonded to form a compound substrate. Finally, the compound substrate is cleaved in such a way that a semiconductor layer is maintained on the oxide layer.

According to yet another embodiment of the present invention, a method for forming a semiconductor device on an insulating substrate comprises providing a substrate with a diffusion barrier layer formed thereon, wherein the diffusion barrier layer has a thickness and a composition that substantially allows the prevention of copper atoms and ions diffusing therethrough. Furthermore, a semiconductor substrate is provided with an insulating layer formed thereon and the substrate and the semiconductor substrate are bonded to form a compound substrate, wherein the diffusion barrier layer and insulating layer form a bond interface. Next, the compound substrate is cleaved so as to obtain a semiconductor layer on the insulating layer. Furthermore, a circuit element is formed in and on the semiconductor layer and a copper metallization layer is formed over the circuit element.

### BRIEF DESCRIPTION OF THE DRAWINGS

The invention may be understood by reference to the following description taken in conjunction with the accompanying drawings, in which like reference numerals identify like elements, and in which:

FIGS. 1a-1e schematically show cross-sectional views of an SOI substrate during various manufacturing stages; and

FIGS. 2a-2b schematically show cross-sectional views of a semiconductor device formed on an insulating substrate at different manufacturing stages according to one illustrative embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

As previously noted, recently, suitable techniques have been developed that allow the formation of SOI substrates with a high quality silicon layer of a thickness of some tens of a nanometer to some hundreds of nanometers, depending on the type of semiconductor device to be formed, on a silicon dioxide layer of a thickness in the range of tenths of a nanometer to several hundred nanometers. Most frequently, a so-called wafer bonding technique is employed in which a first wafer is provided, often referred to as a handle wafer, and a second wafer is provided, often referred to as a donor wafer, wherein a silicon dioxide layer, with a required thickness, is grown on the second wafer. Subsequently, an ion implantation is performed, preferably using hydrogen ions, with the second wafer, wherein ions are implanted through the silicon dioxide layer at a well-defined depth of the second wafer in such a manner that, between the silicon dioxide layer and the peak concentration of the hydrogen, a semiconductor layer with a specified thickness is maintained. After the implantation, the first wafer and the second wafer are bonded together, wherein the silicon dioxide of the second wafer forms a bonding interface with the surface of the first wafer. After the bond process, which involves an anneal step, the compound of the first wafer and the second wafer is subjected to a cleaving process, wherein the region including the implanted hydrogen ions acts as a separation layer so that finally an SOI wafer is obtained having a high-quality silicon layer formed on a silicon dioxide layer. The silicon layer may then be treated by chemical mechanical polishing (CMP) so as to obtain the required surface quality.

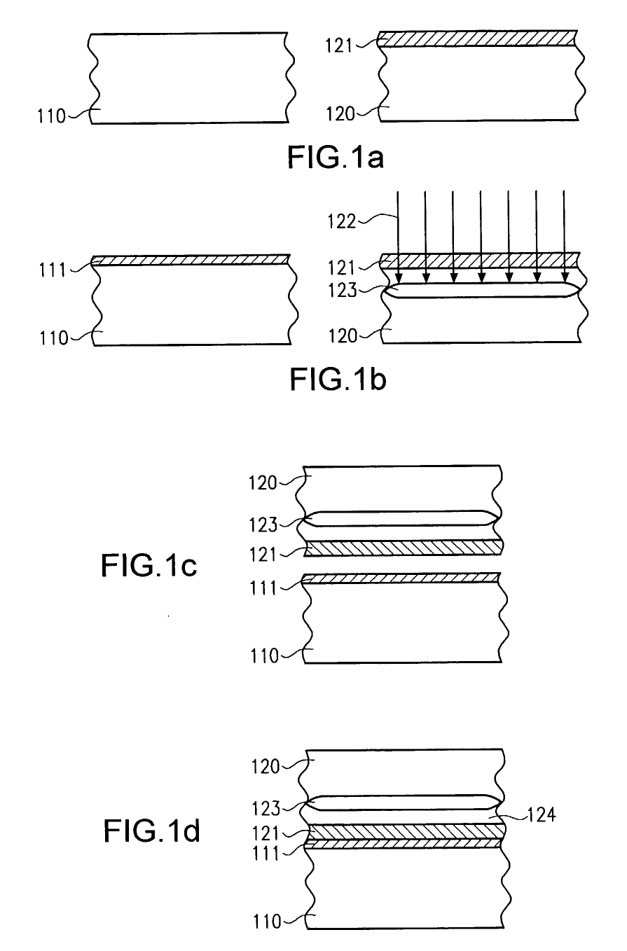

With reference to FIGS. 1a-1e, illustrative embodiments of the present invention will now be described that may, in principle, employ the sequence as described above. In FIG. 1a, a first substrate 110, such as a silicon wafer, a glass wafer or any other appropriate wafer, and a second substrate 120, for example, a silicon wafer or any other appropriate semiconductor substrate, are provided. For instance, the first and second substrates 110, 120 may be standard silicon wafers for standard integrated circuit fabrication as available from a plurality of vendors. The second substrate 120 has formed thereon an insulating layer 121 of required thickness. In one particular embodiment, the insulating layer 121 is a silicon dioxide layer with a thickness in the range of approximately 50 nm to 1 μm. The insulating layer 121 may be formed by any suitable growth and/or deposition method known in the art. For example, the insulating layer 121, when provided as a silicon dioxide layer, may be formed by oxidizing the second substrate 120.

In FIG. 1b, the second substrate 120 is subjected to ion implantation, as indicated by arrows 122, so as to form an implantation region 123, the peak concentration of which is located at a predefined depth that is well controllable by the implantation parameters and the thickness of the insulating layer 121. Preferably, hydrogen ions are implanted with a dose and energy suitable to provide the implantation region 123 approximately 10-500 nm below the insulating layer 121.

The first substrate 110 has formed thereon a diffusion barrier layer 111, the composition and the thickness of which is selected so as to act as a diffusion barrier for copper atoms and ions at elevated temperatures which may occur during the fabrication of semiconductor devices. In one embodiment, the diffusion barrier layer 111 is a silicon nitride layer, which is a well-known dielectric material that effectively prevents copper atoms and ions form mitigating therethrough. The thickness of the diffusion barrier layer 111 may range from 50 nm to several hundred nanometers, depending on process requirements. For instance, if the first substrate 110 is a silicon wafer that will be used as a handle wafer for the further processing and formation of a semiconductor device, it may be advantageous that the silicon nitride layer 111 have a thickness of several hundred nanometers to reduce the chances of copper contamination during the processing of the substrate 110. In the case where the first substrate 110 is a material in which copper has a significantly smaller diffusion coefficient (as compared to silicon), the thickness of the silicon nitride layer 111 may be selected in the range of 50-200 nm. In other embodiments, the diffusion barrier layer 111 may be formed of any appropriate material that acts as an efficient copper gettering layer and that withstands the elevated temperatures occurring during the manufacturing of integrated circuits. In another embodiment, the diffusion barrier layer 111 may include a plurality of layers to adjust the properties of the diffusion barrier layer 111 in a required manner. For instance, metal-containing layers may be provided which effectively prevent or reduce copper diffusion and, if an overall insulating behavior is required and/or superior bonding characteristics of silicon-containing layers to silicon dioxide are required, a silicon nitride layer or silicon dioxide layer and the like may be provided on top of the one or more metal-containing layers. The formation of the diffusion barrier layer 111 may involve any appropriate deposition method, such as plasma enhanced chemical and physical vapor deposition to form, for example, a silicon nitride layer.

FIG. 1c schematically shows the first substrate 110 and the second substrate 120 immediately prior to the bonding process, wherein the diffusion barrier layer 111 and the insulating layer 121 are arranged to face each other.

In FIG. 1d, a compound substrate 130 is formed, including the first substrate 110, the diffusion barrier layer 111, the insulating layer 121 and an active layer 124 defined by the insulating layer 121 and the implantation region 123. As previously noted, bonding the first substrate 110 and the second substrate 120 may require an anneal step to insure the required stability of the compound substrate 130, all of which may be accomplished using known prior art techniques.

FIG.1e schematically shows the first substrate 110 and the second substrate 120 after separation at the implantation region 123. The separation of the two substrates may be accomplished by a water jet at the perimeter of the compound substrate 130 at a position 101 (see FIG. 1d) corresponding to the implantation region 123. The first substrate 110, having the active layer 124 formed on the top thereof, may then be subjected to any surface treatment, such as CMP, to obtain the required surface properties for the further processing of the substrate. The second substrate 120, on the other hand, may be used as a first substrate or as a second substrate in a subsequent process to form an SOI substrate.

As a result, contrary to the conventional SOI substrate, according to the present invention, the second substrate 110 includes the diffusion barrier layer 111 that effectively prevents copper atoms and ions from diffusing through the diffusion barrier layer 111 into the insulating layer 121 and into the active layer 124. It should be noted that the present invention is not limited to the SOI formation process described above, but may be applied to any wafer bond sequence. In other embodiments, the first and second substrates may substantially change their role. For example, in one embodiment, the insulating layer 121 may be formed of silicon nitride or silicon oxynitride instead of silicon dioxide, and the second substrate 120 may be subjected to implantation as shown in FIG. 1b. The first substrate 110 may then be treated to receive a thin oxide layer or may be bonded to the second substrate 120 without further treatment so that the final first substrate 110, as shown in FIG. 1e, may comprise the insulating layer 121 acting as a barrier diffusion layer, wherein possibly a silicon dioxide may be provided as the layer 111.

According to a further variation, a silicon nitride layer and a silicon dioxide layer may be formed on a single substrate and may then be subjected to ion implantation and be bonded to a handle wafer, such as a substantially blank silicon wafer, to obtain, after separation of the compound substrate, an SOI substrate as shown in FIG. 1e. The formation of a silicon nitride layer, and subsequently of a silicon oxide layer, may be performed in separate or in a common deposition process, wherein the thickness of both layers are adjusted as required. Furthermore, during implantation of hydrogen ions, the combined thickness of the silicon nitride layer and the silicon dioxide layer has to be taken into account.

In other embodiments, the diffusion barrier layer 111 may represent a plurality of sub-layers that are designed and stacked to obtain the required barrier and process compatibility characteristics. For instance, an effective copper gettering layer, such as tantalum nitride or titanium nitride, may be embedded into a layer of material that effectively prevents diffusion of tantalum or titanium at elevated temperatures into neighboring materials.

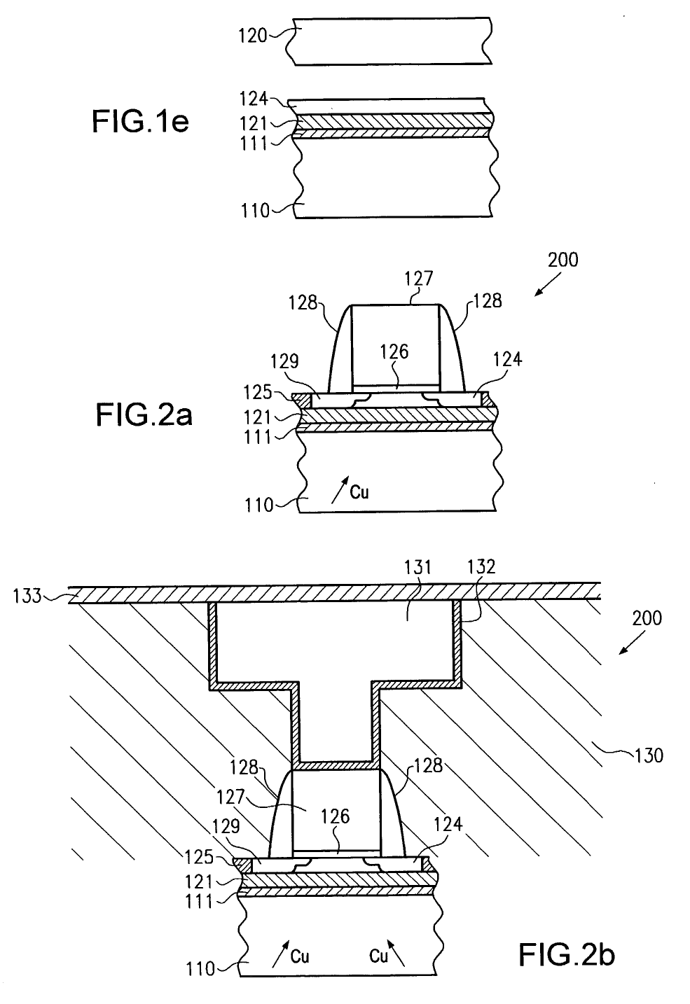

With reference to FIGS. 2a and 2b, a semiconductor device will be described in accordance with further illustrative embodiments of the present invention, wherein a diffusion barrier layer 111 provides for a significantly reduced risk of copper contamination of sensitive semiconductor areas.

In FIG. 2a, a semiconductor device 200, for example, a field effect transistor, is schematically shown, wherein an insulating substrate 110 is used. For the sake of convenience, the substrate 110 and the material layers included therein are denoted by the same reference numbers as in FIGS. 1a-1e. The semiconductor device 200 comprises the barrier diffusion layer 111 and the insulating layer 121, for example, in the form of a buried oxide, as well as the active layer 124. In the active layer 124, an isolation structure 125 is formed, for example, a shallow trench isolation (STI), to define an electrically insulated semiconductor island in the active layer 124. For the sake of simplicity, the semiconductor island is also referred to as the active region and is denoted by the same reference number 124. Within the active region 124, source and drain regions 129 are formed which have a specified dopant profile in the vertical direction as well as in the horizontal direction in FIG. 2a. A gate insulation layer 126 is formed over the active region 124 and provides electrical insulation for a gate electrode 127 formed over the active region 124. Sidewall spacers 128 are provided adjacent to the gate electrode 127.

The semiconductor device 200, as shown in FIG. 2a, may be formed according to well-known process techniques that are similar to conventional bulk devices and, hence, a corresponding description thereof will be omitted. It is, however, important to note that, due to the diffusion barrier layer 111, any copper atoms or ions that may have been applied to the back side of the semiconductor device 200, i.e., to the substrate 110, by means of slightly copper-contaminated process tools, transportation containers, metrology tools, and the like, is effectively reduced.

FIG. 2b schematically shows the semiconductor device 200 in an advanced manufacturing stage. A dielectric layer 130 is formed over the substrate 110 and electrically insulates adjacent active regions 124 from each other. In the dielectric layer 129, a metal layer 131 is formed that is substantially comprised of copper, wherein a second diffusion barrier layer 132 is formed to separate the copper in the line 131 from adjacent materials, such as the gate electrode 127 and the dielectric layer 129. The second diffusion barrier layer 132 may be formed of any appropriate conductive material, such as tantalum, titanium nitride, tantalum nitride, and the like, that effectively suppresses diffusion of copper into the neighboring dielectrics and semiconductor materials. On top of the dielectric layer 129, a third diffusion barrier layer 133 is formed, for example, comprised of silicon nitride, so that the metal line 131 is effectively encapsulated. The dielectric layer 129, the metal line 131 and the third diffusion barrier layer 133 may be referred to as a first metallization layer, wherein one or more metallization layers of similar configuration may be formed over the first metallization layer according to design requirements.

A typical process flow may involve the following steps. After depositing the dielectric layer 129 in the form of silicon dioxide, silicon nitride, and the like, or possibly a low-k material for sophisticated applications, the dielectric layer 129 is patterned by advanced photolithography and etch techniques to form a trench and a via for the metal line 131. Subsequently, the second diffusion barrier layer 132 is deposited, for example, by sputter deposition, and a copper seed layer (not shown) may be formed on the second diffusion barrier layer 132 by CVD or sputter deposition. Thereafter, the bulk copper may be deposited by electroplating and the excess copper may be removed by CMP. Thereafter, the copper surface may be cleaned and the third diffusion barrier layer 133 may be deposited on the clean copper surface. In particular, during the process steps associated in manufacturing the metal line 131, the risk of copper contamination from the back side is particularly increased, wherein, however, according to the present invention, the diffusion barrier layer 111 effectively reduces the probability of copper diffusion into the overlying material layers.

Since the present invention significantly relaxes the requirements set for processing copper in a production line, process management may significantly be simplified and thus may be organized in a more efficient manner, as is presently the case.

It should be noted that the term SOI is to include semiconductor structures formed on an insulating substrate, the active region of which comprises other semiconducting materials than silicon. For instance silicon/germanium devices, gallium/arsenide devices, III-V devices, II-VI devices, and the like are considered to be encompassed in the term SOI device.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. An SOI substrate comprising:
a bulk substrate;
an insulating layer;
an active semiconductor layer positioned above said insulating layer; and
a diffusion barrier layer arranged between the bulk substrate and the active semiconductor layer, wherein a thickness and a composition of said diffusion barrier layer is selected to substantially prevent copper atoms from diffusing therethrough.

2. The SOI substrate of claim 1, wherein said diffusion barrier layer is located between said insulating layer and the bulk substrate.

3. The SOI substrate of claim 1, wherein said insulating layer is at least partially formed of a material that substantially prevents copper atoms and ions from diffusing therethrough.

4. The SOI substrate of claim 1, wherein said diffusion barrier layer is substantially comprised of silicon nitride.

5. The SOI substrate of claim 1, wherein the bulk substrate is substantially comprised of silicon and said insulating layer is substantially comprised of silicon dioxide.

6. The SOI substrate of claim 1, wherein said diffusion barrier layer has a thickness in the range of approximately 50-500 nm.

7. The SOI substrate of claim 1, wherein said barrier diffusion layer is comprised of a plurality of sub-layers, at least one of which acts as a copper diffusion barrier.

8. The SOI substrate of claim 1, wherein said diffusion barrier layer is located between said insulating layer and said active semiconductor layer.

9. A semiconductor device formed on an insulating substrate, comprising:
a bulk substrate layer;
a buried insulating layer;
an active semiconductor layer formed above said buried insulating layer;
a copper-containing metal layer formed over said active semiconductor layer; and
a diffusion barrier layer located between said bulk substrate layer and said active semiconductor layer.

10. The semiconductor device of claim 9, wherein a layer thickness and a composition of said diffusion barrier layer is selected to substantially prevent diffusion of copper atoms and ions therethrough.

11. The semiconductor device of claim 9, wherein said diffusion barrier layer is substantially comprised of silicon nitride.

12. The semiconductor device of claim 9, wherein said diffusion barrier layer has a thickness in the range of approximately 50-500 nm.

13. The semiconductor device of claim 9, wherein said diffusion barrier layer is located between said buried insulating layer and said bulk substrate layer.

14. The semiconductor device of claim 9, wherein said diffusion barrier layer is located between said buried insulating layer and said active semiconductor layer.

15. The semiconductor device of claim 9, wherein said diffusion barrier layer is comprised of a plurality of sub-layers, at least one of which substantially prevents copper diffusion therethrough.

16. A semiconductor device comprising:
a bulk substrate;
an insulating layer electrically insulating said bulk substrate from overlying layers;
a semiconductor layer formed above said insulating layer;
a copper-containing metallization layer formed over said semiconductor layer; and
a diffusion barrier region located so as to substantially prevent copper atoms and ions from diffusing from said substrate into said semiconductor layer.

17. The semiconductor device of claim 16, wherein said insulating layer is at least partially comprised of a material serving as said diffusion barrier region.

18. The semiconductor device of claim 16, wherein said insulating layer is substantially comprised of silicon nitride.

19. The semiconductor device of claim 16, wherein said insulating layer is provided as a multi-layer stack.

20. The semiconductor device of claim 19, wherein said multi-layer stack includes a silicon dioxide layer and a silicon nitride layer.

21. The semiconductor device of claim 20, wherein the silicon nitride layer is located between the silicon dioxide layer and said substrate.

22. The semiconductor device of claim 20, wherein said silicon dioxide layer is formed between said substrate and said silicon nitride layer.

23. A method of forming an SOI substrate having a back side diffusion barrier, the method comprising:
forming a diffusion barrier layer on a first substrate;
forming an insulating layer on a second substrate;
implanting ions into the second substrate through said insulating layer at a predefined depth;
bonding the first and the second substrates to form a compound substrate; and
separating said compound substrate at a depth defined by the implanted ions to obtain the SOI substrate with a semiconductor layer formed on top of said insulating layer.

24. The method of claim 23, wherein forming said diffusion barrier layer includes depositing silicon nitride with a plasma enhanced deposition method.

25. The method of claim 23, wherein forming said diffusion barrier layer includes forming a plurality of sub-layers, at least one of which substantially prevents copper atoms and ions from diffusing therethrough.

26. A method of forming a semiconductor device on an insulating substrate, comprising:
providing said substrate having formed thereon a buried insulating layer and a semiconductor layer formed on the buried insulating layer, and a diffusion barrier layer, a layer thickness and a composition of which are selected so as to substantially prevent copper atoms and ions from diffusing therethrough;
forming a circuit element in and on the semiconductor layer; and
forming a copper-containing metallization layer over said circuit element.

27. The method of claim 26, wherein providing said substrate includes:
providing a first substrate with a diffusion barrier layer formed thereon, providing a second substrate with an insulating layer formed thereon, bonding the first and second substrates to form a compound substrate having a bond interface between the diffusion barrier layer and the insulating layer; and
separating the compound substrate so as to obtain said semiconductor layer.
